(19) United States
(12) Patent Application Publication
(10) Pub. No.: US 2025/0104616 A1
(43) Pub. Date: Mar. 27, 2025

(54) ELECTRONIC DEVICE AND ELECTRONIC CIRCUITRY THEREOF

(71) Applicant: PanelSemi Corporation, New Taipei City (TW)

(72) Inventor: Rung-Nan LU, New Taipei City (TW)

(21) Appl. No.: 18/895,885

(22) Filed: Sep. 25, 2024

Related U.S. Application Data
(60) Provisional application No. 63/584,971, filed on Sep. 25, 2023.
(60) Provisional application No. 63/616,066, filed on Dec. 29, 2023.

(51) Int. Cl. G09G 3/32; H01L 27/12

(52) U.S. Cl. CPC G09G 3/32; H10D 86/40; H10D 86/60; G09G 2300/0819; G09G 2330/021; G09G 2360/145

(57) ABSTRACT

An electronic circuitry and an electronic device. The electronic circuitry includes a plurality of light-emitting components and a plurality of driving circuits corresponding to the light-emitting components. The driving circuit includes a transistor for delivering a driving signal to a corresponding light-emitting component, a detecting unit for providing a detecting output in response to the corresponding light-emitting component, and a feedback-control unit for directing the transistor to regulate the driving signal in response to the detecting output.

### CROSS REFERENCE TO RELATED APPLICATIONS

This Non-provisional application claims priority under 35 U.S.C. § 119 (a) on Patent Application No(s). 63/584,971 filed in United States of America on Sep. 25, 2023 and Patent Application No(s). 63/616,066 filed in United States of America on Dec. 29, 2023, the entire contents of which are hereby incorporated by reference.

### BACKGROUND

### Technology Field

The disclosure relates to an electronic circuitry and an electronic device using the same.

### Description of Related Art

Conventional LED driving technologies use a current-controlling transistor to regulate the flow of current through an LED. Referring to FIG. 1, this transistor is typically operated in the saturation region, where, under ideal circumstances, the drain electrode current is solely determined by the gate-source voltage (the voltage from the gate electrode to the source electrode of the transistor) and remains unaffected by changes in the drain-source voltage (the voltage from the drain electrode to the source electrode of the transistor). This operation principle ensures the constancy of the LED driving current (Id, the driving current of the LED) even when LED characteristics such as the forward voltage of the LED vary due to process variations or temperature effects, which can impact the drain-source voltage. The current-controlling transistor and the LED are electrically connected in series, hence any changes in LED characteristics influence the drain-source voltage, but not the Id. It should be known that VD, VDD, VG here are respectively Drain Voltage, Supply Voltage, and Gate Voltage.

However, this traditional technology has a trade-off. Operating in the saturation region results in a higher the drain-source voltage, compared to the non-saturation region, leading to increased power consumption across the current-controlling transistor.

### SUMMARY

One or more exemplary embodiments of this disclosure are to provide an electronic circuitry and an electronic device with a light-emitting component driven by a current-controlling transistor to meet requirements of lower power consumption.

An electronic device is disclosed, it comprises a substrate, a plurality of light-emitting components and a plurality of driving circuits. The light-emitting components are arranged on the substrate, the driving circuits electrically connect and correspond to the light-emitting components respectively. The light-emitting component emit light in response to a driving signal and the driving signal can be a driving current. The driving circuit includes a transistor for controlling the driving signal, a detecting unit and a feedback-control unit. The transistor includes an input terminal and two output terminals and delivers the driving signal (e.g. driving current) to a corresponding one or corresponding ones of the light-emitting components by one of the two output terminals; wherein the transistor for controlling the driving signal defines a characteristic curve which is defined by one output current of the transistor versus a voltage gap between the two output terminals of the transistor. The characteristic curve further defines an operation region and an output conductance within the operation region, the output conductance defines an absolute value of a ratio of an output current change to a voltage gap change. The operation region further defines a first region and a second region, an output conductance in the first region is greater than an output conductance of the second region. The transistor for controlling the driving signal is operated within the first region. The detecting unit delivers a detection output in response to a corresponding one of the light-emitting components. The feedback-control unit directs the transistor to regulate the driving signal, ex. the driving current.

An electronic circuitry is also provided in this disclosure, the electronic circuitry includes a plurality of light-emitting components and a plurality of driving circuit electrically connects and corresponds to the light-emitting components respectively. The light-emitting components emits light in response to a driving signa, ex. a driving current. The driving circuit includes a transistor for controlling the driving signal, a detecting unit and a feedback-control unit. The transistor includes an input terminal and two output terminals and delivers the driving signal to a corresponding one or corresponding ones of the light-emitting components through one of the two output terminals. The transistor defines a characteristic curve in which the characteristic curve is defined by one output current versus a voltage gap between the two output terminals of the transistor. The characteristic curve further defines an operation region and an output conductance within the operation region. The output conductance defines an absolute value of a ratio of a change in output current to a change in voltage gap. The operation region defines a first region and a second region, an output conductance in the first region is greater than an output conductance of the second region. The transistor for controlling the driving signal is operated within the first region. The detecting unit delivers a detection output in response to a corresponding one of the light-emitting components. The feedback-control unit directs the driving-current control transistor to regulate the driving current. Furthermore, the electronic circuitry can be modularized.

The abovementioned electronic device or electronic circuitry may further have the characteristics as follows:

In one embodiment, the transistor for controlling the driving signal is a bipolar junction transistor (BJT), an insulated gate bipolar transistor (IGBT), or a field-effect transistor (FET).

In one embodiment, the FET includes types of metal-oxide-semiconductor field-effect transistor (MOSFET), metal semiconductor field effect transistor (MESFET) and thin-film transistor (TFT), and the driving-current control transistor may be one of them.

In one embodiment, the transistor for controlling the driving signal is a field effect transistor (FET); the input terminal of the transistor is a gate electrode, and the two output terminals are a drain electrode and a source electrode; the first region denotes a linear region of the FET, while the second region denotes a saturation region of the FET.

In one embodiment, one or ones of the driving circuits are at least partially arranged on the substrate.

In one embodiment, the detecting unit senses the light from the corresponding one of the light-emitting components and delivers the detection output in response thereto.

In one embodiment, the detecting unit includes a photo diode.

In one embodiment, the detecting unit is formed of thin film on the substrate.

In one embodiment, the photo diode is formed of thin film on the substrate.

In one embodiment, the detecting unit senses the driving signal, which drives the corresponding one of the light-emitting components, and delivers the detection output in response thereto.

In one embodiment, the detecting unit includes a resistor electrically connecting with the corresponding one of the light-emitting components in serial, and the feedback-control unit directing the driving-current control transistor based on a voltage drop across the resistor.

In one embodiment, the driving circuits are at least partially formed on the substrate.

In one embodiment, the driving circuits is at least partially arranged upon an integrated circuit.

In one embodiment, the light-emitting components defines a voltage drop thereof; the voltage gap of one of the driving-current control transistors is less than or equal to the voltage drop of a corresponding one of the light-emitting components.

In one embodiment, the voltage gap of one of the driving-current control transistors is less than or equal to two-thirds of the voltage drop of a corresponding one of the light-emitting components

In one embodiment, the voltage gap of one of the transistors for controlling the driving signal is less than or equal to half of the voltage drop of a corresponding one of the light-emitting components.

### BRIEF DESCRIPTION OF THE DRAWINGS

FIG. 1 is a circuit diagram showing a conventional circuitry for a light emitting component;

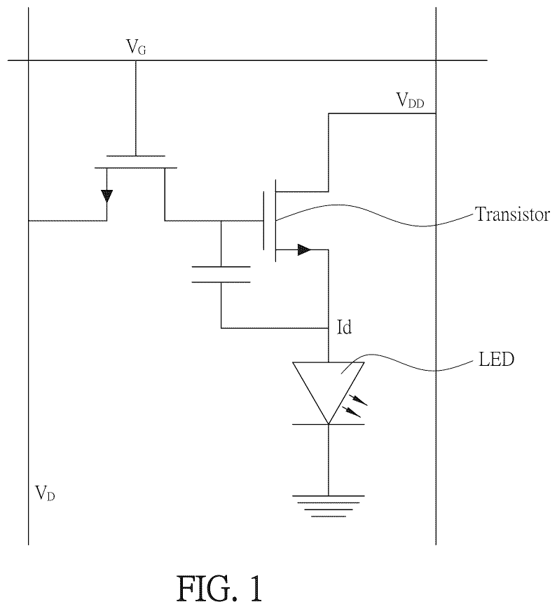

FIG. 2 is a circuit diagram showing an embodiment of the present invention;

FIG. 3 is a graph showing a characteristic curve of a transistor in one embodiment of the present invention;

FIG. 4 is a circuit diagram of one embodiment of the present invention;

FIG. 5 is a circuit diagram of one embodiment of the present invention;

FIG. 6 is a circuit diagram of one embodiment of the present invention; and

FIG. 7 is a circuit diagram of one embodiment of the present invention.

### DETAILED DESCRIPTION OF THE DISCLOSURE

The disclosure will become more fully understood from the detailed description and accompanying drawings, which are given for illustration only, and thus are not limitative of the present disclosure.

The present disclosure will be apparent from the following detailed description, which proceeds with reference to the accompanying drawings, wherein the same references relate to the same elements.

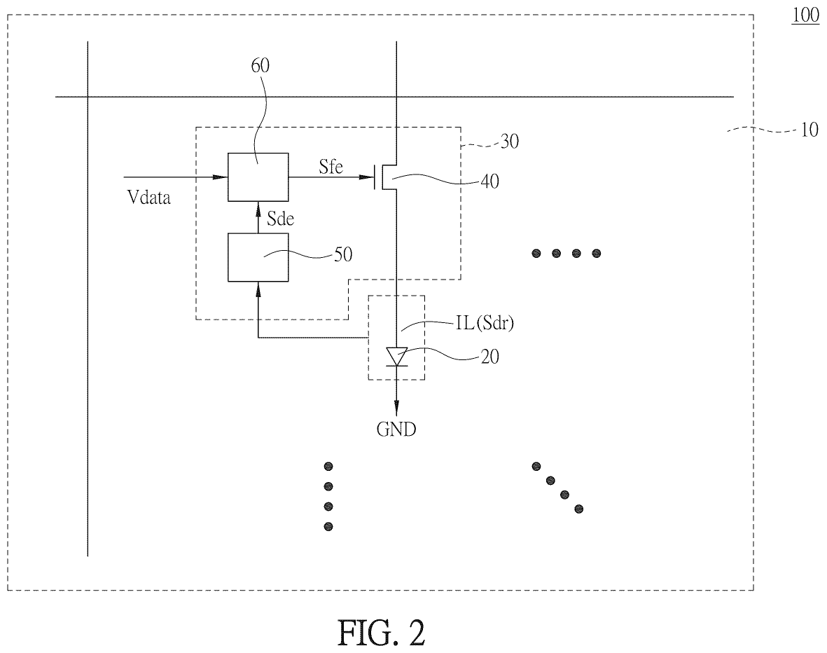

FIG. 2 is a schematic diagram of a generic embodiment according to the present invention. The electronic device 100 in FIG. 2 mainly includes a substrate 10, a plurality of light-emitting components 20 and a plurality of driving circuits 30. The light-emitting components 20 are arranged on the substrate 10, and the driving circuits 30 electrically connects the light-emitting components 20 and correspond to the light-emitting components 20 respectively.

One or ones of the light-emitting components 20 emit light in response to a corresponding driving signal Sdr, ex a driving current IL. The driving circuit 30 includes a transistor 40, a detecting unit 50 and a feedback-control unit 60. The transistor 40 controls the driving signal and can be considered as a driving-signal control transistor 40.

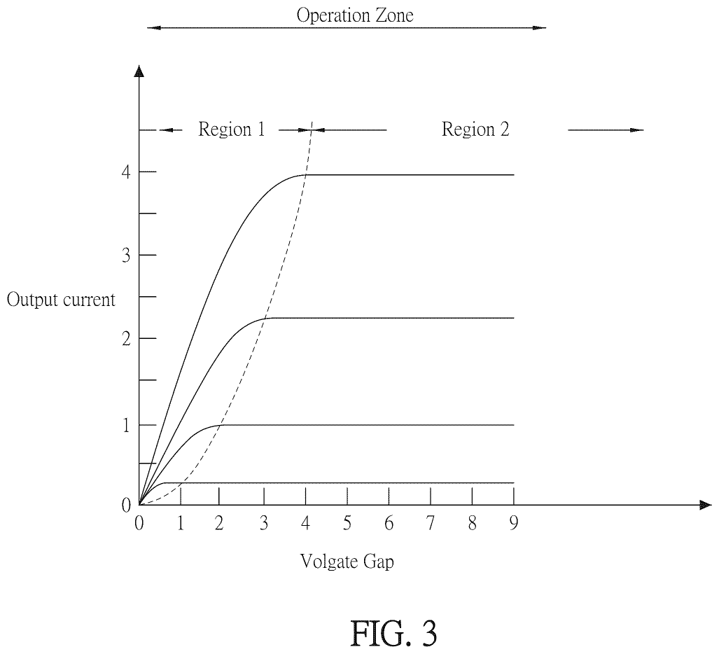

The transistor 40, a thin-film transistor (TFT) here for example, includes an input terminal and two output terminals, and delivers the driving signal Sdr, ex the driving current IL, to a corresponding one or corresponding ones of the light-emitting components 20 through one of the two output terminals. To be noted, the transistor 40 electrically connects the corresponding one of the light-emitting components 20 either in direct or indirect manner, in which an additional member may be disposed therebetween. The transistor 40 defines a characteristic curve as shown in FIG. 3, and the characteristic curve is established by plotting one output current of the transistor 40 versus a voltage gap between the two output terminals of the transistor 40. The characteristic curve defines an operation region and an output conductance within the operation region, the output conductance defines an absolute value of a ratio of an output current change (change in output current) to a voltage gap change (change in the voltage gap). To be noted, the characteristic curve shown in FIG. 3 is only for exemplary and does not limit the scope of this disclosure.

As shown in FIG. 3, the operation region of the characteristic curve further defines a first region (Region 1) and a second region (Region 2), and an output conductance in the first region (Region 1) is greater than an output conductance of the second region (Region 2). Herein, the transistor 40 is operated within first region (Region 1).

The detecting unit 50 detects the driving signal Sdr, which drives the corresponding one of the light-emitting components 20 and delivers a detection output Sde in response to the driving signal Sdr of a corresponding one of the light-emitting components 20.

The feedback-control unit 60 delivers a feedback output Sfe to direct the transistor 40 for regulating the driving signal Sdr, ex the driving current IL.

The transistor 40 operates in the first region of the operation region of its own characteristic curve thereof to regulate the driving signal Sdr, ex. the driving current IL, so as to reduce its own power consumption. In other words, the driving signal Sdr is determined based on the feedback output Sf provided by the feedback-control unit 60, and this feedback output Sf is the result of detecting the current or light emitted from the corresponding light emitting component 20 by the detecting unit 50.

To be noted, there are more layouts over the substrate 10, such as one or ones trace layers and other electrical components. In addition, there are generally more transistors provided in the driving circuit 30 than the amounts of transistors 40 illustrated in FIG. 2. The trace layer is usually individually from the driving circuits 30, but for easy understanding and element simplifying, the trace layer and other electrical components can also be contained within a generic terminology as we say the driving circuits 30 in this disclosure. Furthermore, it will be clear that the terminology “respective” or “respectively” means a relationship may refer only to a one-on-one relationship, but also to a one-on-multiple relationship, a multiple-on-multiple relationship, or a multiple-on-one relationship.

In one case, the driving circuits 30 are at least partially arranged on the substrate 10.

In one case, the substrate 10 may be transparent or non-opaque. In one case, the substrate 10 may also be flexible or rigid, a single layer structure or compound layer(s) structured.

In one case, the light-emitting components 20 may comprise types of LEDs varying from regular ones, to mini LEDs, or micro LEDs, from organic LEDs to inorganic LEDs; in another case, the light-emitting components 20 may comprise types of electroluminescent elements, such as quantum dots.

In one case, one or ones of the driving circuits 30 is at least partially formed on the substrate 10, especially is at least partially formed of thin film by thin film process on the substrate 10, in which the transistor 40 for controlling the driving signal may be formed of thin film by thin film process on the substrate 10. In one case, the driving circuit 30 is at least partially arranged upon an integrated circuit (IC), in which the transistor 40 for controlling the driving signal may be formed within the IC.

To be noted, the transistor 40 for controlling the driving signal can be a bipolar transistor (bipolar junction transistor, BJT), an insulated gate bipolar transistor (IGBT), a field-effect transistor (FET), which the FET may include types of metal-oxide-semiconductor field-effect transistor (MOSFET), metal semiconductor field effect transistor (MESFET) and thin-film transistor (TFT), or the like. To be noted, the characteristic curve of each type of the transistor 40 for controlling the driving signal meets the criteria mentioned-above and the plotting in FIG. 3.

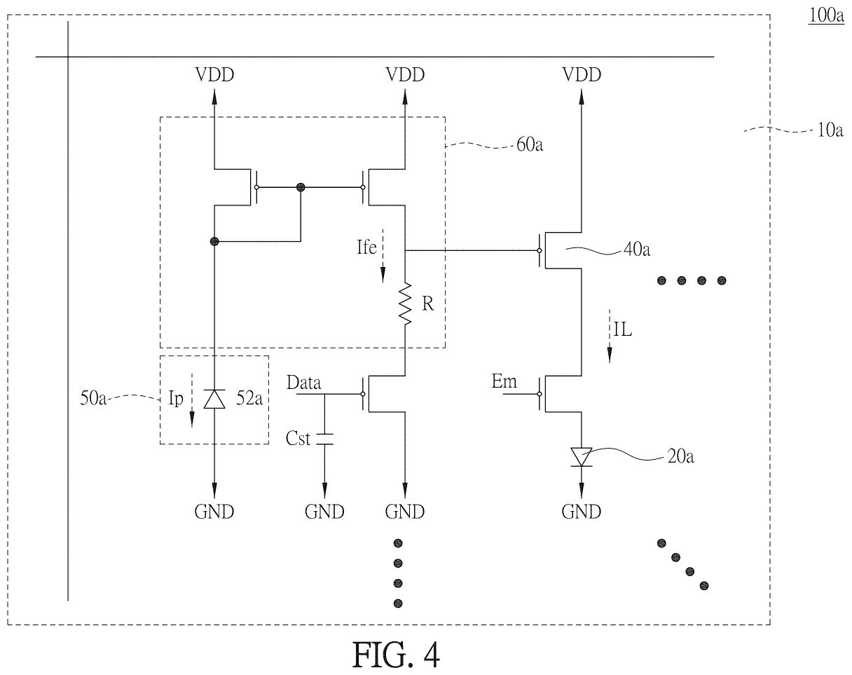

Here are more embodiments according to this invention, respectively shown in FIG. 4 to FIG. 7.

An electronic device 100a shown in FIG. 4 depicts a detecting unit 50a, which senses the light from the corresponding one of the light-emitting components 20a and delivers the detection output in response thereto. In this case, a photo diode 52a is provided to detect the light of the targeted light-emitting component 20a. In one case, the photo diode 52a may be formed of thin film by thin film process on the substrate 10. In one case, the photo diode 52a may be formed of thin film on the substrate 10. A feedback-control unit 60a is provided to direct the transistor 40a, a TFT in this case, to regulate the driving current IL from the result of detecting the light emitted by the target light-emitting component 20a by the detect unit 50a.

In this embodiment, the light-emitting component 20a is driven by the driving current IL. The light emitted by the light-emitting component 20a is detected by the photo diode 52a, which generates a current Ip. This current Ip, after passing through the feedback unit 60a (ex. a feedback circuit), generates a feedback current Ife that is directly proportional to the current Ip. This feedback current Ife maintains the transistor 40 for controlling the driving signal operating in the first region (Region 1) of the operation zone.

The transistor 40 for controlling the driving signal in FIG. 2 and FIG. 4, can be a MOSFET (or TFT) for example, in which a linear region thereof denotes the first region of the characteristic curve thereof, while a saturation region thereof denotes the second region of their characteristic curve.

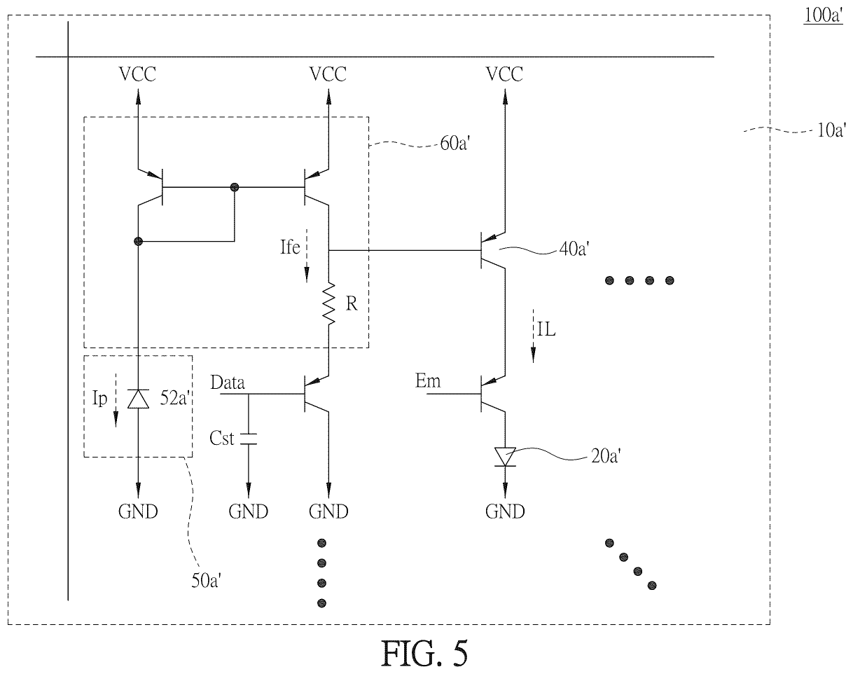

In FIG. 5, the transistor 40a′ for controlling the driving signal of the electronic device 100a′ is a BJT instead of an MOSFET (or a TFT). In this case, the transistor 40a′ (BJP) of the electronic device 100a′ may use the whole concept of layout design in in the electronic device 100a. In this case, a saturation region of the characteristic curve of the transistor 40a′ denotes the first region the while an active region denotes the second region of the characteristic curve of the transistor 40a′.

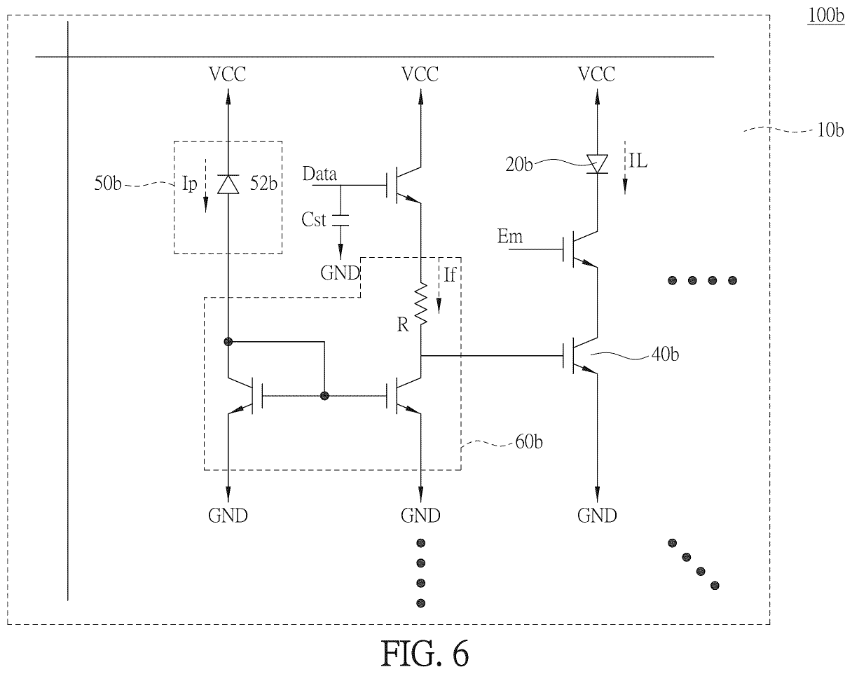

In FIG. 6, the transistor 40b for controlling the driving signal of the electronic device 100b is an insulated gate bipolar transistor; wherein a saturation region thereof stands for first region of the characteristic curve thereof, while an active region thereof stands for second region. The technique feature in FIG. 6 is as equivalent as it is in FIGS. 4 and 5. The electronic device 100b depicts a detecting unit 50b, which senses the light from the corresponding one of the light-emitting components 20b and delivers the detection output in response thereto. A photo diode 52b is provided to detect the light of the targeted light-emitting component 20b. A feedback-control unit 60b is provided to direct the transistor 40b for controlling the driving signal to regulate the driving current IL from the result of detecting the light emitted by the target light-emitting component 20b from the detect unit 50b. In details, the light emitted by the light-emitting component 20b is detected by the photo diode 52b, which generates a current Ip; and this current Ip, after passing through the feedback unit 60b, generates a feedback current Ife that is directly proportional to the current Ip. This feedback current Ife maintains the driving-current control transistor 40b operating in the first region in the operation zone, so as to regulate the driving current IL delivering to the targeted light-emitting component 20b.

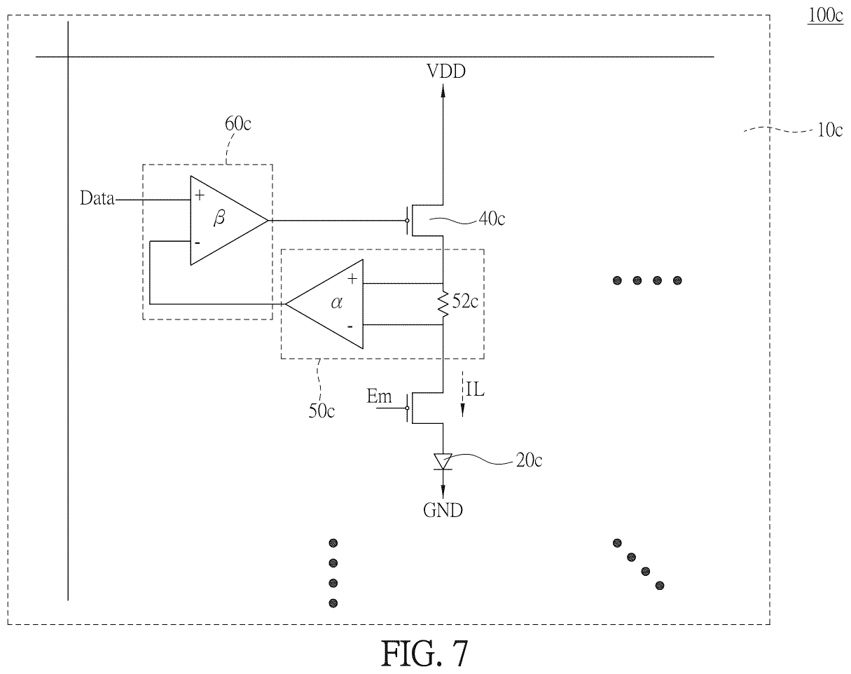

In FIG. 7, the electronic device 100c depicts a detecting unit 50c, which senses the current from the corresponding one of the light-emitting components 20c and delivers the detection output in response thereto. In this case, the detect unit 50c includes a resistor 52c with a resistance value R, the resistor 52c electrically connects with the corresponding one of the light-emitting components 20c in serial, and the feedback-control unit 60c directing the transistor 40c for controlling the driving signal, a TFT for example, based on a voltage drop across the resistor 52c. In this case, the resistor 52c is arranged between the transistor 40c and the light-emitting components 20c. In this case, both of the detect unit 50c and the feedback-control unit 60c comprise an amplifier, and each of the amplifier defines a coefficient alpha (a) and beta (B). Here are some the equations for detailed comprehension.

$$( ( Vdata - IL * R * α ) * β - Vt ) * Vds * k = IL ; \\ IL * ( R * α * β * k + 1 ) = ( Vdata * β - Vt ) * Vds * k ;$$

wherein k is a coefficient proportional to the transconductance of transistor 40c;
Vdata is a data voltage delivered to the driving circuits 30;
Vt is a threshold voltage of the transistor 40c; and
Vds is a voltage from the drain to the source of the transistor 40c.

When β is great enough, the driving current IL approaches the value of Vdata/(R*α). While the resistor 52c is considered as a current sensing resistor, as long as the resistance value R thereof is low enough, a voltage drop across the resistor 52c and the power consumption are low as well. Only the value of Vdata/α, which approaches to IL*R, is needed to be considered appropriately, then the low power consumption is accomplished.

In FIG. 7, the transistor 40c can be a BJT or IGBT.

In one case, the light-emitting components 20 and the driving-current control transistors 40 are relatively corresponding. The light-emitting components 20 defines a voltage drop thereof; the voltage gap of the transistors 40 for controlling the driving signal is less than or equal to the voltage drop of a corresponding one of the light-emitting components 20 n another case, the voltage gap of the transistors 40 is less than or equal to two-thirds of the voltage drop of corresponding one of the light-emitting components 20. In a third case, the voltage gap of the transistors 40 is less than or equal to half of the voltage drop of corresponding one of the light-emitting components 20.

Accordingly, the electronic device in this invention has a plurality of light-emitting components that are regulated respectively by driving circuits. The driving circuits control the amount of current that flows through the light-emitting components, which determines how bright they are. A driving-current control transistor operates in its first region of the operation region to output a driving current Id, reducing its own power consumption. The driving current IL is determined based on the feedback output from the feedback-control unit, which detects either the current or light from the target light emitting component. In other words, the electronic device uses the driving-current control transistor in the specific first region of the operation zone to maintain a high output conductance, which leads to a reduction in power consumption. The driving circuits also use the feedback-control unit to ensure that the driving current Id is maintained at the desired level. Overall, the driving circuits in this invention are designed to be more efficient than conventional driving circuits in way of power consumption. This could lead to a number of benefits, such as reduced energy consumption for lighting system or longer battery life for portable devices.

What is claimed is:

1. An electronic device, comprising a substrate, a plurality of light-emitting components and
a plurality of driving circuits;
wherein the light-emitting components are arranged on the substrate, the driving circuits electrically connect the light-emitting components and correspond to the light-emitting components respectively;
wherein one or ones of the light-emitting components emits lights in response to a driving signal; and
wherein the driving circuit includes:
a transistor including an input terminal and two output terminals, wherein the transistor delivers the driving signal to a corresponding one or corresponding ones of the light-emitting components by one of the two output terminals;
wherein the transistor defines a characteristic curve in which the characteristic curve is defined by one output current versus a voltage gap between the two output terminals, and the characteristic curve defines an operation region and an output conductance within the operation region, wherein the output conductance defines an absolute value of a ratio of an output current change to a voltage gap change;
wherein the operation region further defines a first region and a second region, an output conductance of the first region is greater than an output conductance of the second region, and the transistor is operated within the first region;
a detecting unit delivering a detection output in response to a corresponding one of the light-emitting components; and
a feedback-control unit directing the transistor in response to the detection output to regulate the driving signal.

2. The electronic device as claimed in claim 1, wherein the transistor is a bipolar junction transistor (BJT), an insulated gate bipolar transistor (IGBT), or a field-effect transistor (FET).

3. The electronic device as claimed in claim 2, wherein the FET includes types of metal-oxide-semiconductor field-effect transistor (MOSFET), metal semiconductor field effect transistor (MESFET) and thin-film transistor (TFT).

4. The electronic device as claimed in claim 1, wherein the transistor is a field effect transistor (FET); the input terminal is a gate, and the two output terminals are a drain and a source; the first region denotes a linear region of the FET, while the second region denotes a saturation region of the FET.

5. The electronic device as claimed in claim 1, wherein the detecting unit senses the light emitted from the corresponding one of the light-emitting components and delivers the detection output in response thereto.

6. The electronic device as claimed in claim 1, wherein the detecting unit detects the driving signal, which drives the corresponding one of the light-emitting components, and delivers the detection output in response thereto.

7. The electronic device as claimed in claim 6, wherein the detecting unit includes a resistor electrically connecting with the corresponding one of the light-emitting components in serial, and the feedback-control unit directing the transistor based on a voltage drop across the resistor.

8. The electronic device as claimed in claim 1, wherein the driving circuits are at least partially formed on the substrate.

9. The electronic device as claimed in claim 1, wherein each of the driving circuits is at least partially arranged upon an integrated circuit.

10. The electronic device as claimed in claim 1, wherein each of the light-emitting components defines a voltage drop thereof; the voltage gap of one of the driving-current control transistors is less than or equal to the voltage drop of a corresponding one of the light-emitting components.

11. The electronic device as claimed in claim 10, wherein the voltage gap of one of the transistors is less than or equal to two-thirds of the voltage drop of a corresponding one of the light-emitting components.

12. The electronic device as claimed in claim 10, wherein the voltage gap of one of the driving-current control transistors is less than or equal to half of the voltage drop of a corresponding one of the light-emitting components.

13. An electronic circuitry, comprising:
a plurality of light-emitting components, each of the light-emitting components configured with lighting in response to an driving signal; and
a plurality of driving circuits corresponding to the light-emitting components respectively;
wherein the driving circuits includes:
a transistor including an input terminal and two output terminals, wherein the transistor delivers the driving signal to a corresponding one or corresponding ones of the light-emitting components by one of the two output terminals;
wherein the transistor defines characteristic curve in which the characteristic curve is defined by one output current versus a voltage gap between the two output terminals, and the characteristic curve defines an operation region and an output conductance within the operation region, wherein the output conductance defines an absolute value of a ratio of an output current change to a voltage gap change;
wherein the operation region further defines a first region and a second region, an output conductance of the first region is greater than an output conductance of the second region, and the transistor is operated within the first region;
a detecting unit delivering a detection output in response to a corresponding one of the light-emitting components; and
a feedback-control unit directing the transistor to regulate the driving signal.

14. The electronic circuitry as claimed in claim 13, wherein the transistor is a bipolar junction transistor (BJT), an insulated gate bipolar transistor (IGBT), or a field-effect transistor (FET).

15. The electronic circuitry as claimed in claim 14, wherein the FET includes types of metal-oxide-semiconductor field-effect transistor (MOSFET), metal semiconductor field effect transistor (MESFET) and thin-film transistor (TFT).

16. The electronic circuitry as claimed in claim 13, wherein the transistor is a field effect transistor (FET), the input terminal of the transistor is a gate electrode, and the two output terminals are a drain electrode and a source electrode of the transistor; the first region denotes a linear region of the FET, while the second region denotes a saturation region of the FET.

17. The electronic circuitry as claimed in claim 13, wherein the detecting unit detects the light from the corresponding one of the light-emitting components and delivers the detection output in response thereto.

18. The electronic circuitry as claimed in claim 17, wherein the detecting unit includes a photo diode.

19. The electronic circuitry as claimed in claim 13, wherein the detecting unit detects the driving signal from the corresponding one of the light-emitting components and delivers the detection output in response thereto.

20. The electronic circuitry as claimed in claim 19, wherein the detecting unit includes a resistor electrically connecting with the corresponding one of the light-emitting components in serial, and the feedback-control unit directing the transistor based on a voltage drop across the resistor.

21. The electronic circuitry as claimed in claim 13, wherein the light-emitting components defines a voltage drop thereof; the voltage gap of one of the transistors is less than or equal to the voltage drop of a corresponding one of the light-emitting components.

22. The electronic circuitry as claimed in claim 21, wherein the voltage gap of one of the transistors is less than or equal to two-thirds of the voltage drop of a corresponding one of the light-emitting components.

23. The electronic circuitry as claimed in claim 21, wherein the voltage gap of one of the transistors is less than or equal to half of the voltage drop of a corresponding one of the light-emitting components.
